(19) United States
(12) Patent Application Publication
(10) Pub. No.: US 2026/0343771 A1
(43) Pub. Date: Oct. 29, 2026

(54) EMBODIMENTS TO SCALE AN IN-RACK SCALE-UP FABRIC

(71) Applicant: DELL PRODUCTS L.P., Round Rock, TX (US)

(72) Inventors: Claudio DESANTI, Santa Cruz, CA (US); Joseph LaSalle WHITE, San Jose, CA (US); Macen Kanemi SHINSATO, Georgetown, TX (US)

(73) Assignee: DELL PRODUCTS L.P., Round Rock, TX (US)

(21) Appl. No.: 19/189,227

(22) Filed: Apr. 24, 2025

(51) Int. Cl. H05K 7/02; H05K 7/14

(52) U.S. Cl. CPC H05K 7/026; H05K 7/1487

(57) ABSTRACT

Increasing demand for computing resources due to machine learning and artificial intelligence applications has created a need for scaling units with more processors. Presented herein are embodiments that can at least double the number of graphics processing units (GPUs) in a single scale-up fabric domain compared to current offerings. In one or more embodiments, two racks may be connected via an interconnect cable system, allowing for efficient high-density, high-computation environments. In one or more embodiments, the interconnect cable system provides signal connectivity between compute trays and switches, enabling a compact scalable unit with a significant number of GPUs connected via a scale-up fabric. Embodiments of the interconnect cable system comprise copper-based cabling, fiber-optic-based cabling, or a combination thereof.

### BACKGROUND

### A. Technical Field

The present disclosure relates generally to information handling systems. More particularly, the present disclosure relates to data centers and/or computing centers.

### B. Background

The subject matter discussed in the background section shall not be assumed to be prior art merely as a result of its mention in this background section. Similarly, a problem mentioned in the background section or associated with the subject matter of the background section should not be assumed to have been previously recognized in the prior art. The subject matter in the background section merely represents different approaches, which in and of themselves may also be inventions.

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use, such as financial transaction processing, airline reservations, enterprise data storage, or global communications. In addition, information handling systems may include a variety of hardware and software components that may be configured to process, store, and communicate information and may include one or more computer systems, data storage systems, and networking systems.

The ever-increasing development and use of machine learning and artificial intelligence (ML/AI) applications has created a dramatic increase in demand for computing resources and processing resources. Graphics processing units, with their specially designed architectures, are particularly well suited for using in ML/AI applications—both training and inferencing. With increasingly complex ML/AI models, more and more processing systems are needed.

Thus, the exponentially growing complexity of ML/AI models and their ever-growing voracious need for data have created needs for data centers with vast numbers of processing units and supporting infrastructure. The supporting infrastructure, including information handling systems, such as network switches, and cabling, have also become more complex and more closely tied to the ML/AI deployment. For example, in addition to needing large numbers of complex processing information handling systems, aspects such as physical placement, type of cabling, and network topology should be considered. Because of the staggering number of computation operations that are involved in most modern ML/AI applications, even a small fraction of a second delay in processing aggregates into a significant amount.

Accordingly, it is highly desirable to find new, more efficient ways to structure data centers/computing centers to achieve high density, high-computation environments.

### BRIEF DESCRIPTION OF THE DRAWINGS

References will be made to embodiments of the disclosure, examples of which may be illustrated in the accompanying figures. These figures are intended to be illustrative, not limiting. Although the accompanying disclosure is generally described in the context of these embodiments, it should be understood that it is not intended to limit the scope of the disclosure to these particular embodiments. Items in the figures may not be to scale.

FIG. 1 depicts an example NVL72 system from Nvidia Corporation, a multinational corporation headquartered in Santa Clara, California.

FIG. 2A graphically depicts wiring of a switch, according to embodiments of the present disclosure.

FIG. 2B graphically depicts the connections from the switch connectors to the switch processors, according to embodiments of the present disclosure.

FIG. 3A graphically depicts example structure of a compute tray, which also shows the straight connections between graphics processing units (GPUs) and connectors, according to embodiments of the present disclosure.

FIG. 3B alternatively represents connections between compute tray connections and the GPUs of the compute tray, according to embodiments of the present disclosure.

FIG. 4 depicts a parallel NVLink-based scale-up fabric of an NVL72 system.

FIG. 5 depicts an example of typical intra-rack cabling, including the connectors.

FIG. 6 depicts a passive interconnect cable system or interconnect cable cartridge system 605 and a rack system 620.

FIG. 7 depicts an isometric view of a rack system, like the rack system of FIG. 6.

FIG. 8 graphically depicts, for comparison, the rack layouts of product offerings for Nvidia 805, AMD 810, and Intel 815.

FIG. 9 depicts a structure of a two-rack system, according to embodiments of the present disclosure.

FIG. 10 depicts an isometric view of an interconnect cable system 1005, according to embodiments of the present disclosure.

FIG. 11 depicts a side view of the cable and connectors 1100 of an interconnect cable system (e.g., interconnect cable system 1005) for communicatively coupling a compute tray to a switch, according to embodiments of the present disclosure.

FIG. 12 depicts a scale-up fabric structure, according to embodiments of the present disclosure.

FIG. 13 illustrates a view of a front rack and a back rack of an implementation, according to embodiments of the present disclosure.

FIG. 14A and FIG. 14B a four-rack compact Scalable Unit (SU) that is capable of supporting 288 GPUs and the switches for all fabrics (i.e., scale-up fabric, scale-out fabric, front-end fabric, and management fabric), according to embodiments of the present disclosure.

FIG. 15 depicts a data center layout with a compute tray side and a switch side, according to embodiments of the present disclosure.

FIG. 16 depicts a scalable unit housing 144 GPUs system, which is able to utilize all copper-based connections in the cartridges of the interconnect cable system 1605 for the scale-up fabric, according to embodiments of the present disclosure.

FIG. 17 depicts an example method for forming a dual-rack system, according to embodiments of the present disclosure.

FIG. 18 depicts a simplified block diagram of an information handling system, according to embodiments of the present disclosure.

FIG. 19 depicts an alternative block diagram of an information handling system, according to embodiments of the present disclosure.

### DETAILED DESCRIPTION OF EMBODIMENTS

In the following description, for purposes of explanation, specific details are set forth in order to provide an understanding of the disclosure. It will be apparent, however, to one skilled in the art that the disclosure can be practiced without these details. Furthermore, one skilled in the art will recognize that embodiments of the present disclosure, described below, may be implemented in a variety of ways, such as a process, an apparatus, a system/device, or a method on a tangible computer-readable medium.

Components, or modules, shown in diagrams are illustrative of exemplary embodiments of the disclosure and are meant to avoid obscuring the disclosure. It shall be understood that throughout this discussion that components may be described as separate functional units, which may comprise sub-units, but those skilled in the art will recognize that various components, or portions thereof, may be divided into separate components or may be integrated together, including, for example, being in a single system or component. It should be noted that functions or operations discussed herein may be implemented as components. Components may be implemented in software, hardware, or a combination thereof.

Furthermore, connections between components or systems within the figures are not intended to be limited to direct connections. Rather, data between these components may be modified, re-formatted, or otherwise changed by intermediary components. Also, additional or fewer connections may be used. It shall also be noted that the terms “coupled,” “connected,” “communicatively coupled,” “interfacing,” “interface,” or any of their derivatives shall be understood to include direct connections, indirect connections through one or more intermediary devices, and wireless connections. It shall also be noted that any communication, such as a signal, response, reply, acknowledgement, message, query, etc., may comprise one or more exchanges of information.

Reference in the specification to “one or more embodiments,” “preferred embodiment,” “an embodiment,” “embodiments,” or the like means that a particular feature, structure, characteristic, or function described in connection with the embodiment is included in at least one embodiment of the disclosure and may be in more than one embodiment. Also, the appearances of the above-noted phrases in various places in the specification are not necessarily all referring to the same embodiment or embodiments.

The use of certain terms in various places in the specification is for illustration and should not be construed as limiting. The terms “include,” “including,” “comprise,” “comprising,” and any of their variants shall be understood to be open terms, and any examples or lists of items are provided by way of illustration and shall not be used to limit the scope of this disclosure.

A service, function, or resource is not limited to a single service, function, or resource; usage of these terms may refer to a grouping of related services, functions, or resources, which may be distributed or aggregated. The use of memory, database, information base, data store, tables, hardware, cache, and the like may be used herein to refer to system component or components into which information may be entered or otherwise recorded. The terms “data,” “information,” along with similar terms, may be replaced by other terminologies referring to a group of one or more bits, and may be used interchangeably. The terms “packet” or “frame” shall be understood to mean a group of one or more bits. The term “frame” shall not be interpreted as limiting embodiments of the present invention to Layer 2 networks; and, the term “packet” shall not be interpreted as limiting embodiments of the present invention to Layer 3 networks. The terms “packet,” “frame,” “data,” or “data traffic” may be replaced by other terminologies referring to a group of bits, such as “datagram” or “cell.” The words “optimal,” “optimize,” “optimization,” and the like refer to an improvement of an outcome or a process and do not require that the specified outcome or process has achieved an “optimal” or peak state.

It shall be noted that: (1) certain steps may optionally be performed; (2) steps may not be limited to the specific order set forth herein; (3) certain steps may be performed in different orders; and (4) certain steps may be done concurrently.

Any headings used herein are for organizational purposes only and shall not be used to limit the scope of the description or the claims. Each reference/document mentioned in this patent document is incorporated by reference herein in its entirety.

Any embodiment or embodiments described herein are not necessarily limited strictly to the features expressly described for that specific embodiment and may also (or alternatively) include properties and/or features (e.g., ingredients, components, members, elements, parts, regions, property, and/or functions) described for one or more separate embodiments. Accordingly, the various features of a given embodiment or embodiments may be combined with and/or incorporated into another embodiment or embodiments. Disclosure of certain features relative to a specific embodiment or embodiments should not be construed as limiting application or inclusion of said features to the specific embodiment or embodiments. Rather, it will be appreciated that other embodiments may also include such features.

It shall also be noted that although embodiments described herein may be within the context of rack systems and/or compute systems using graphics processing units (GPUs), aspects of the present disclosure are not so limited. Accordingly, the aspects of the present disclosure may be applied or adapted for use in other contexts.

### A. General Introduction

As noted above, the rapid escalation of machine learning and artificial intelligence (ML/AI) applications has created a dramatic increase in demand for computing resources and processing resources. Graphics processing units, with their specially designed architectures, are particularly well suited for using in ML/AI applications—both training and inferencing. With increasingly complex ML/AI models, more and more processing capacity is needed.

Multiple entities, particularly those wanting to develop and/or deploy ML/AI applications, desire high-density rack-scale GPU solutions. One such system is the NVL72 system from Nvidia Corporation.

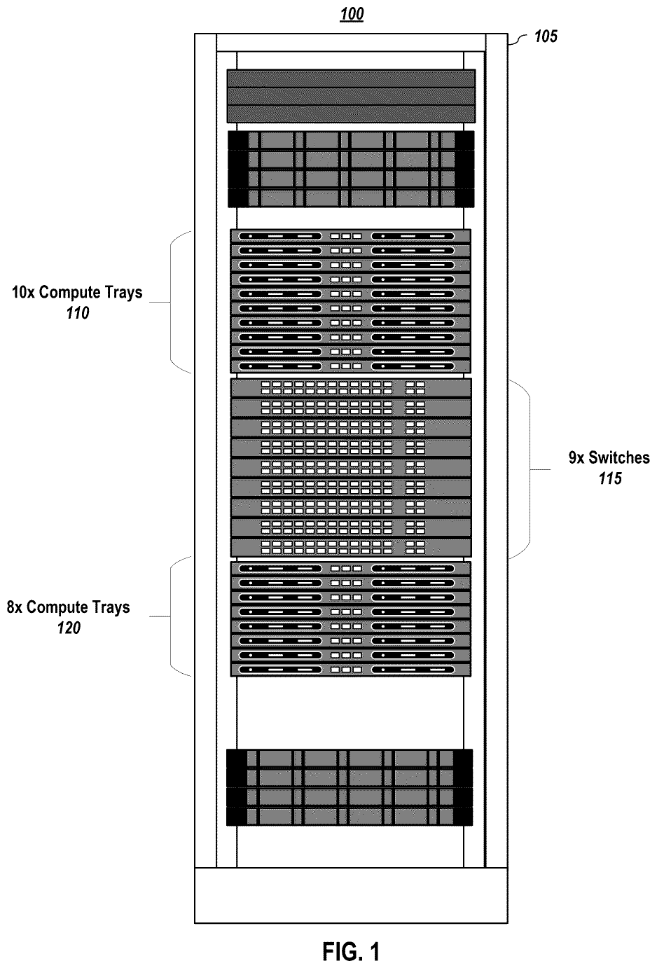

FIG. 1 depicts an example NVL72 system 100. The NVL72 system typically comprises eighteen (18) compute sleds (or trays) 110 and 120 and nine (9) switches 115 for data traffic processing—all housed within a rack 105. In an NVL72 system, each compute tray usually comprises four (4) Blackwell GPUs and two Grace processors. The nine switches (which are typically NVSwitches) implement or help form an NVLink-based scale-up fabric, which is an intra-rack fabric that connects all GPUs. Each NVSwitch includes two Quantum-3 switching application specific integrated circuits (ASICs).

The system may comprise additional elements, such as power supplies, cooling system(s), redundancy system(s), additional processing information handling system(s), among other elements common to a network or data center rack.

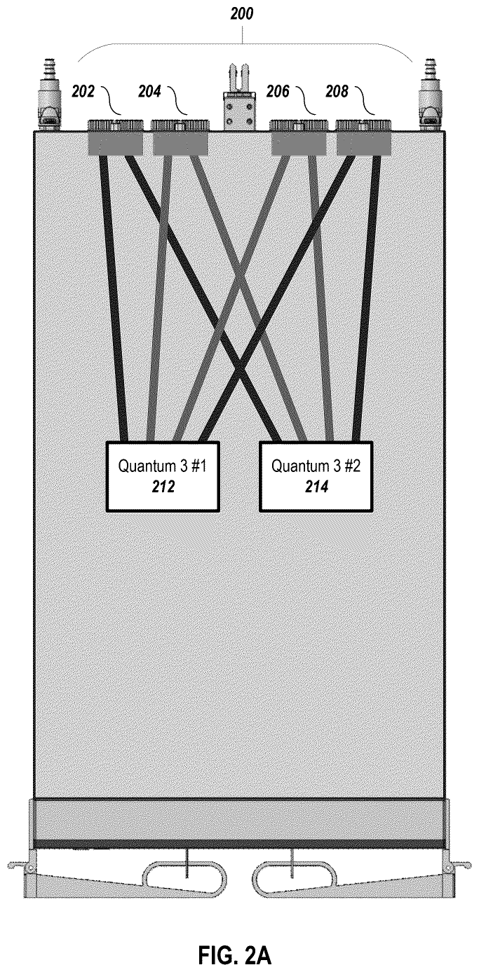

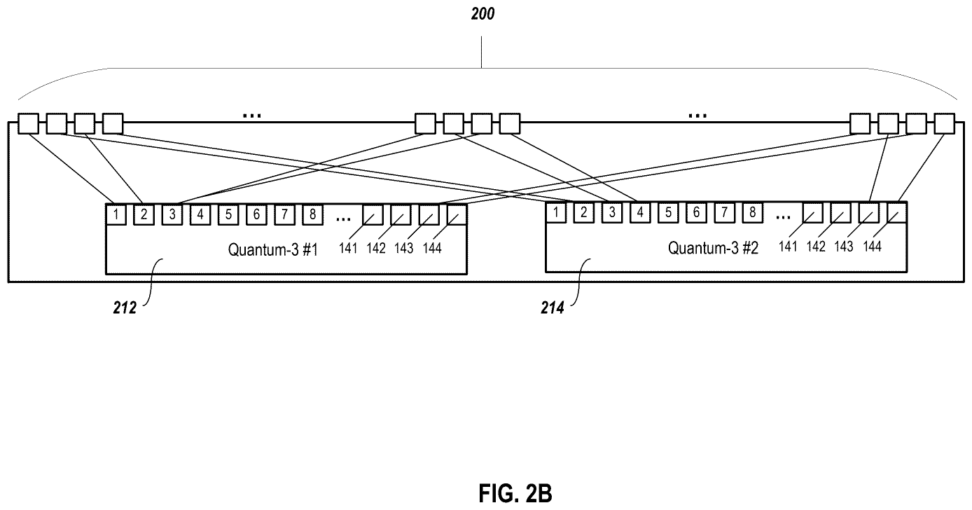

In one or more embodiments, the switch may be wired as shown in FIG. 2A, in which the connectors 202-208 connect to each processor 212 and 214 and allow for crossover/switching of data. FIG. 2B graphically depicts the connections from the switch connectors to the switch processors 212 and 214.

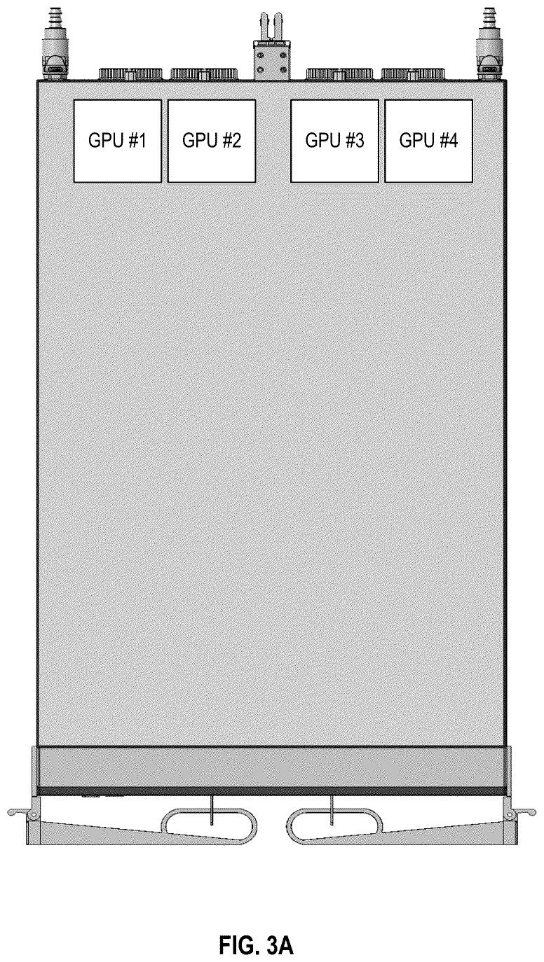

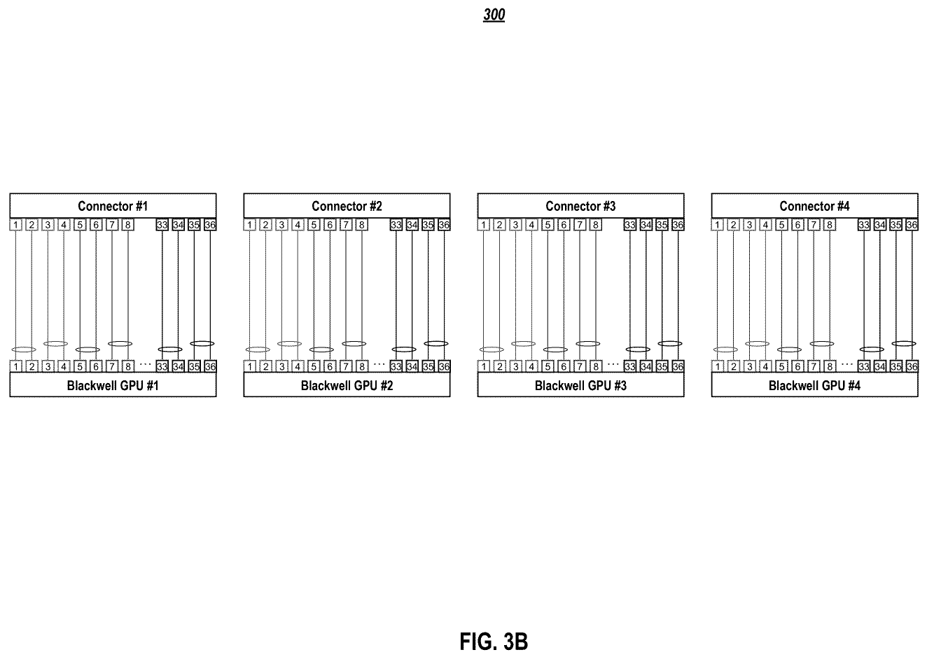

FIG. 3A graphically depicts example structure of a compute tray, which also shows the straight connections between GPUs and connectors, according to embodiments of the present disclosure. FIG. 3B alternatively represents connections between compute tray connections and the GPUs of the compute tray, according to embodiments of the present disclosure.

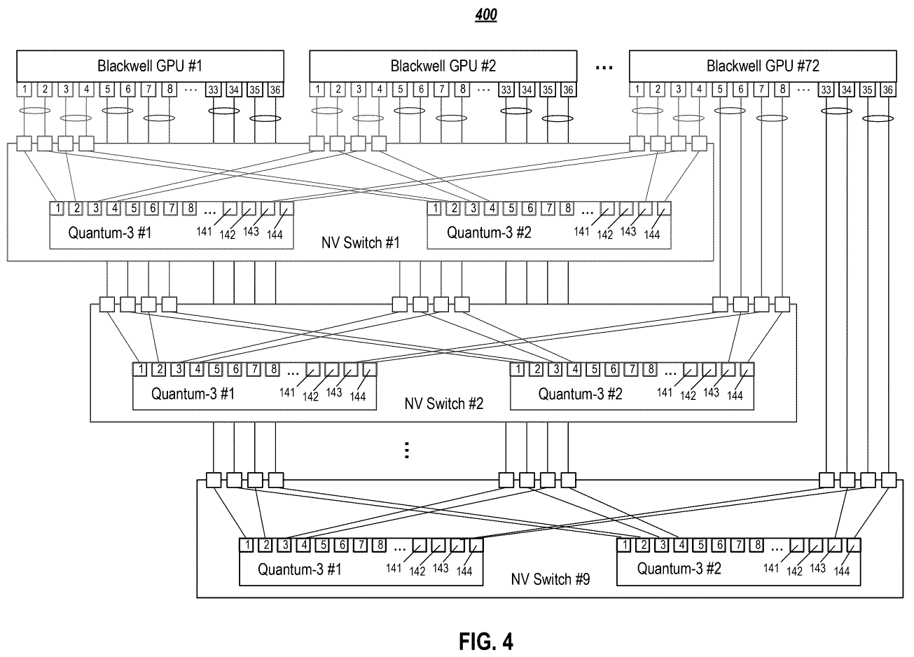

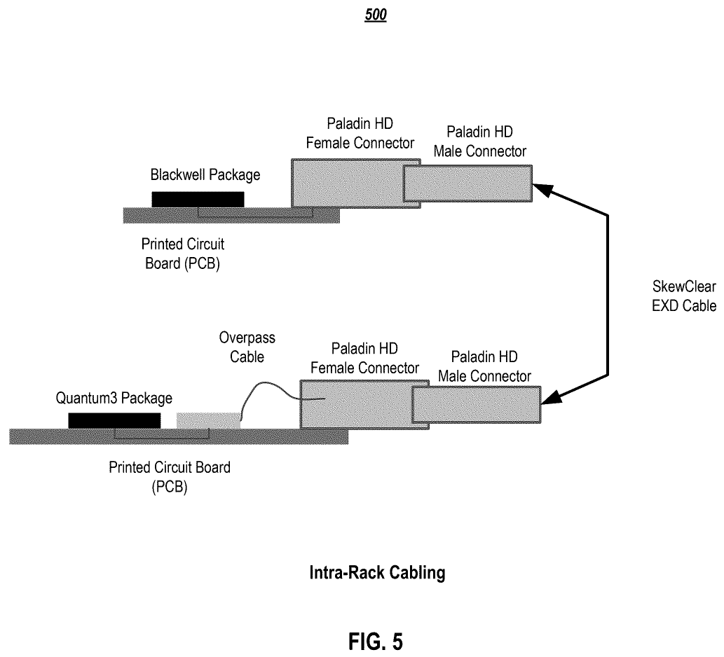

Depicted in FIG. 4 is a parallel NVLink-based scale-up fabric of an NVL72 system. As shown, 72 GPUs are connected to 18 Quantum-3 switching ASICs, and each GPU connects two serial links to each Quantum-3 switching ASIC. The intra-rack cabling of NVL72, which forms a scale-up fabric, is typically all based on copper twin-axial cables, grouped in a large cable cartridge, which is installed on the back of a rack. FIG. 5 depicts a typical intra-rack cabling, including the connectors.

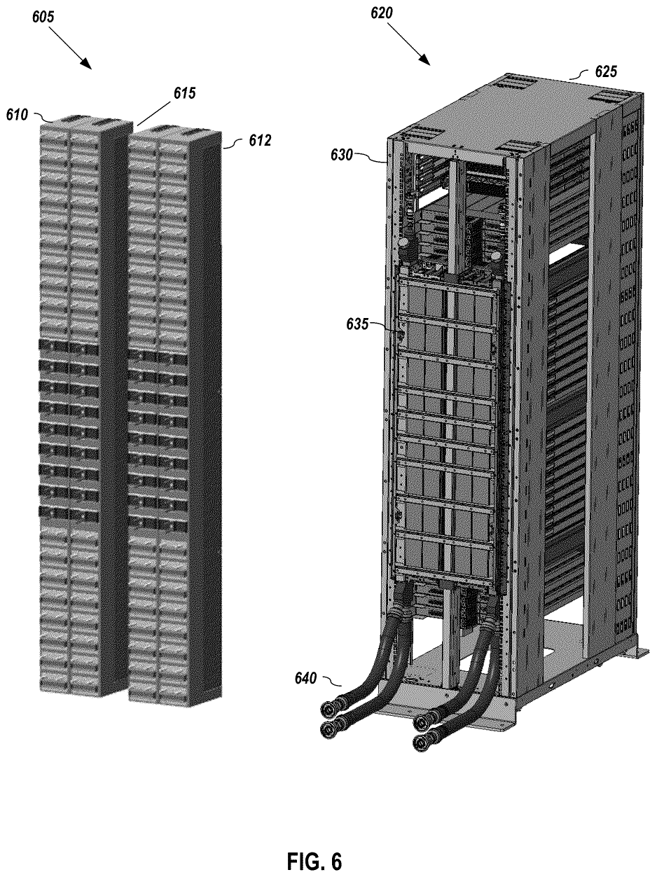

FIG. 6 depicts a passive interconnect cable system or interconnect cable cartridge system 605. The interconnect cable system 605 houses the cabling and the connectors (e.g., connectors shown in FIG. 5) and provides a stable mechanical structure in which to plug compute sleds/trays and switches. The interconnect cable system 605 comprises two vertical columns of cartridges 610 and 612 with spacing 615 to accommodate a power bar. Also depicted in FIG. 6 is a rack 620 that comprises a front end or front face 625 (in which compute trays, switches, and other components may be inserted and removed) and a rear or back face 630 (in which an interconnect cabling system 635 may be install or positioned. Also depicted are additional components, such as connectors 640 to facilitate liquid cooling to address heat generated by system components.

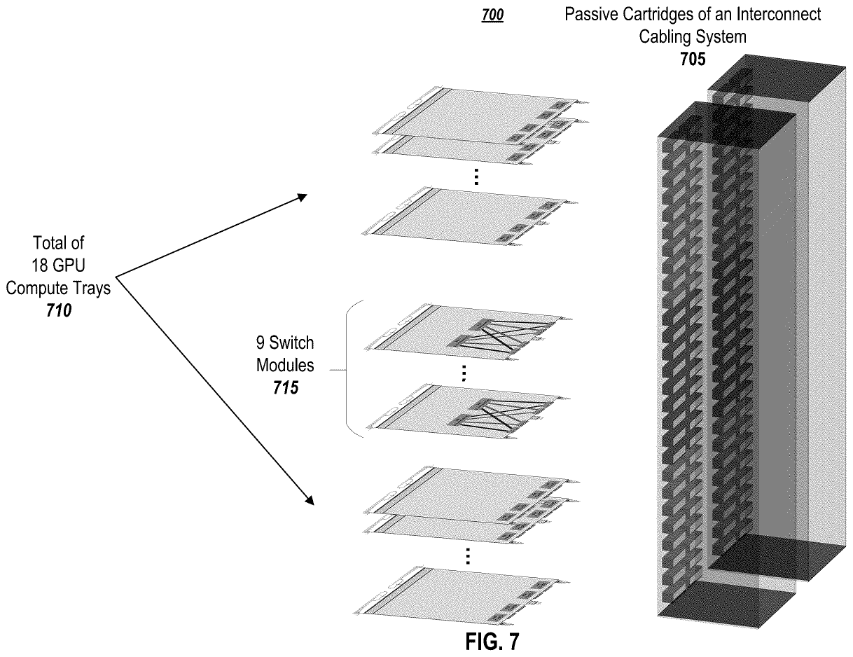

FIG. 7 depicts an isometric view of a rack system, like the rack system 620 of FIG. 6. The rack system is configured like an NVL72 system, which comprises 18 GPU compute trays 710 and nine (9) switching modules 715.

FIGS. 6 and 7 depict a current state-of-the-art for GPU density in a rack. Specifically, the maximum GPU count for a unit is 72 GPU which are limited to a single rack. However, with increasing demand for compute resources, customers are wanting even larger base solutions.

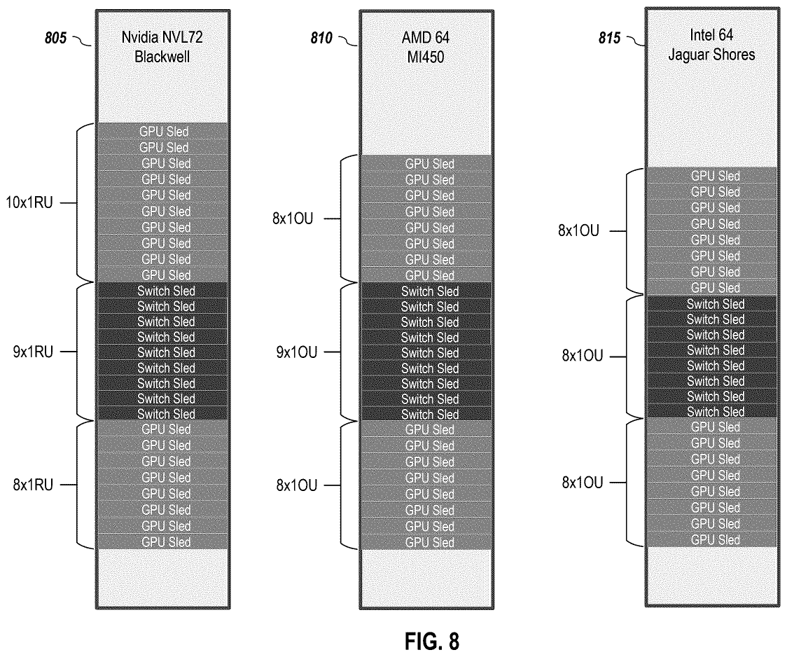

One inherent problem with the current state-of-the-art, like the NVL72 design, is that the switches are packaged in horizontal switch trays that take vertical space in the rack. Therefore, that rack space cannot be used for compute sleds that include GPUs. It shall be noted that this problem is not limited to Nvidia offerings; other GPU vendors, such as Intel and AMD, also have similar issues. FIG. 8 graphically depicts, for comparison, the rack designs of present or future offerings from Nvidia 805, AMD 810, and Intel 815. In each case, precious rack space is consumed by switch sleds, which reduce the number of GPU compute trays that can be housed within the rack system.

### B. System and Method Embodiments

To help with the rapid deployment of high levels of compute resources, preconfigured designs are provided for customers. While some product designs, like the NVL72rack unit, provides exascale computing level, it is still not enough for some demands. Even higher compute designs are required. However, there are limitations, such as physical limitations, which have limited the ability to provide a base unit or scalar unit of compute resources.

Embodiments herein overcome the prior limitations and provide novel systems that may comprise at least up to double the number of GPUs in a single scale-up fabric domain than that of current offerings. In one or more embodiments, two racks may be combined to form a single scale-up fabric of compute trays. The racks may be coupled via the backsides of the racks using an embodiment of a novel interconnect cable system (or interconnect cable cartridge system). As will be explained in more detail below, the rack configuration and the interconnect cable system may take different configurations. For example, in one or more embodiments, one of the two racks may be dedicated to host compute trays and the other rack may comprise host switches. Alternatively, in one or more embodiments, each rack may comprise a mixture of compute trays and switches. The interconnect cable system may vary in configuration depending upon the rack configuration, whether it comprises a homogenous set of core devices (e.g., compute trays vs. switches) or a heterogeneous mix of compute trays and switches. In one or more embodiments, the racks may include one or more additional devices or systems.

### 1. Homogenous Rack Embodiments

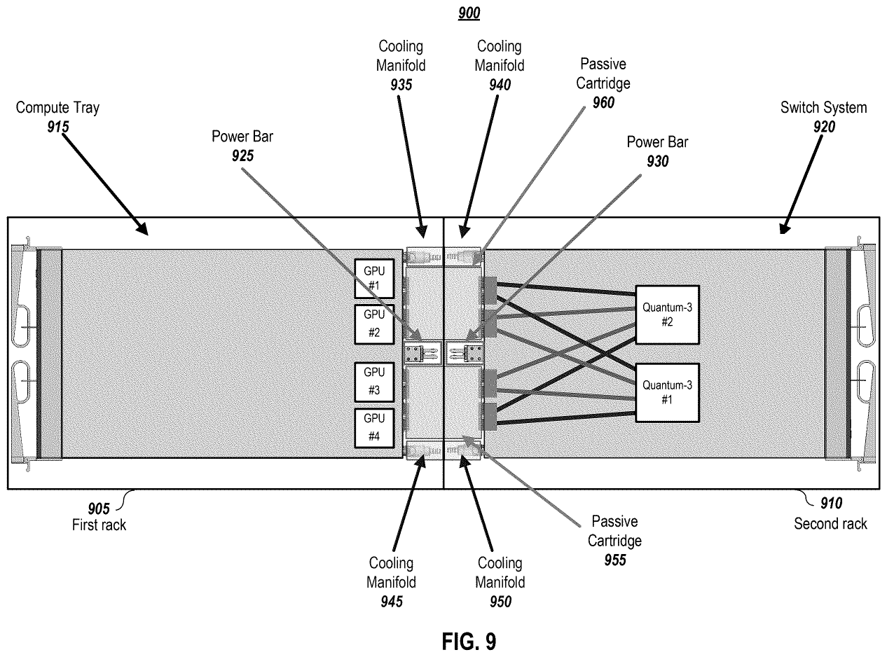

FIG. 9 depicts an implementation of a two-rack system, according to embodiments of the present disclosure. Depicted is a top view of the two-rack system, in which there is a first rack 905 and a second rack 910. The rack may be an Open Rack (OR) (e.g., OR version 3 rack), which is an Open Compute Project standard for a rack and power delivery architecture, but other racks may be used. Depicted in the first rack 905 is a compute tray 915, and depicted in the second rack 910 is a switch system 920. The compute tray plugs into a compute tray connector on one side of an interconnect cable cartridge (which may comprise one or more passive cartridges 955 and 960), and the switch 920 plugs into a switch connector on an opposite side of the interconnect cable cartridge). The interconnect cable cartridge system 955 may accommodate a power bar or bars 925, 930 that provide power via connectors to each of the trays 915 and 920. In one or more embodiments, the system may also accommodate one or more cooling manifolds 935-950. It shall be noted that more or fewer components or features may exist in various embodiments.

Thus, in one or more embodiments, each rack hosts its power bar and one or more cooling manifolds, that enable plugging the compute sleds and switches. The two racks may be joined by two passive cartridges 955, 960 that provide the vertical scale-up connectivity among compute sleds and switches in the racks. Alternatively, a rack with double depth may replace the two racks, thereby avoiding alignment issues.

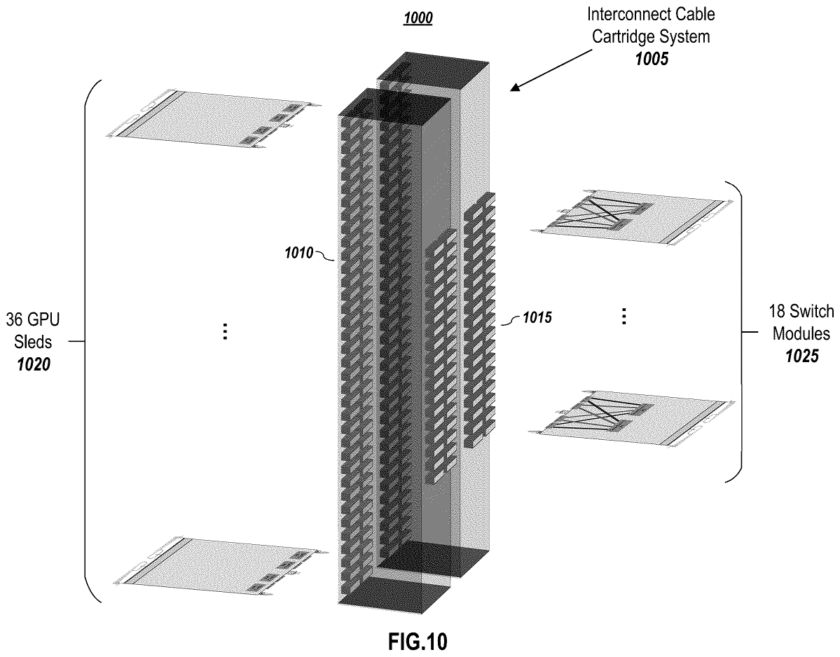

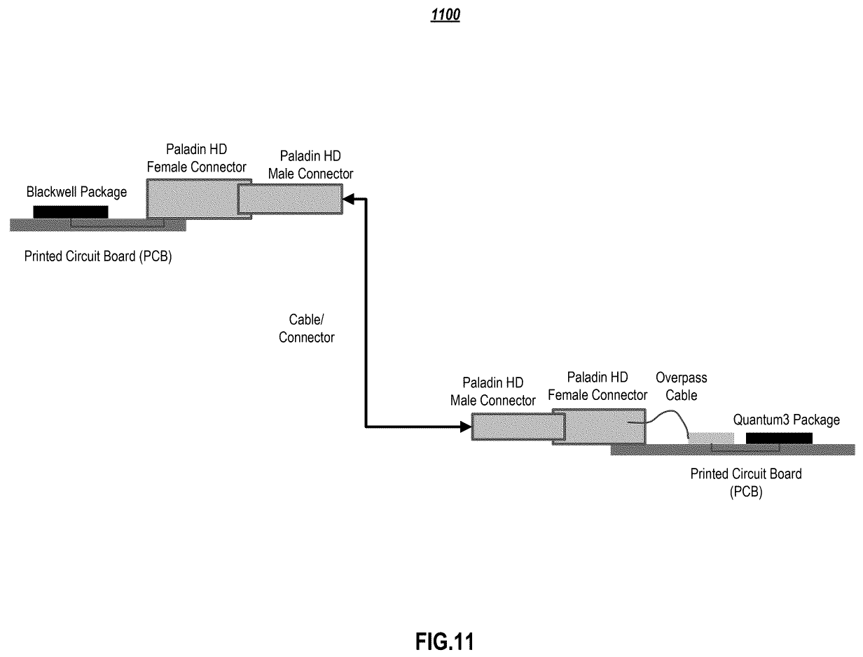

FIG. 10 depicts an isometric view of an interconnect cable system 1005, according to embodiments of the present disclosure. In the illustrated embodiment, one face 1010 of the interconnect system 1005 comprises compute tray connectors for receiving GPU/compute trays 1020, and the opposite face 1015 comprises switch connectors for receiving switch modules 1025. FIG. 11 depicts a side view of the cable and connectors 1100 of an interconnect cable system (e.g., interconnect cable system 1005) for communicatively coupling a compute tray to a switch, according to embodiments of the present disclosure.

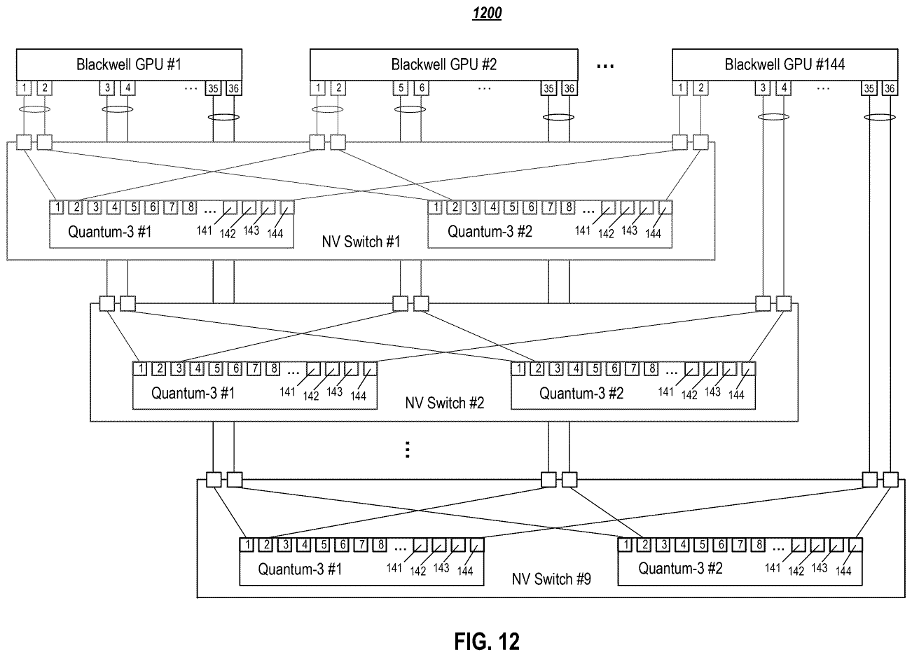

As shown, the cartridges provide signal connectivity between the front connectors (connecting to the compute sleds) and the back connectors (connecting to the switches). Such embodiments enable a system with 144 GPUs fully interconnected in the same scale-up fabric domain, with 36 compute sleds and 18 switches—doubling the size of the current state-of-the-art NVL72. An embodiment of a scale-up fabric structure is illustrated in FIG. 12.

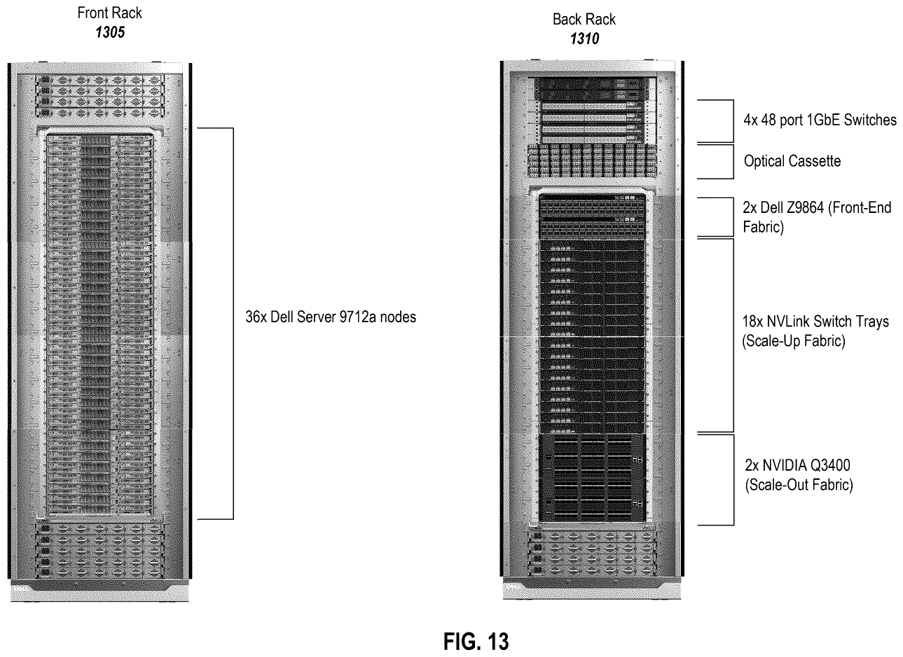

It shall be noted that this design of such embodiments has several advantages. First, embodiments may leverage existing racks and active components (i.e., compute sleds and switches)—modification may be limited to the interconnect cable system to support the double depth connectivity. Second, at least the rack hosting the switches may also host other utilities (e.g., management switches, structured optical cabling cassettes, storage devices). Third, all active components are fully serviceable at least via their front faces. FIG. 13 illustrates a view of a front rack 1305 and a back rack 1310 of an implementation, according to embodiments of the present disclosure. Note that additional components/systems may be included on the switch rack 1310.

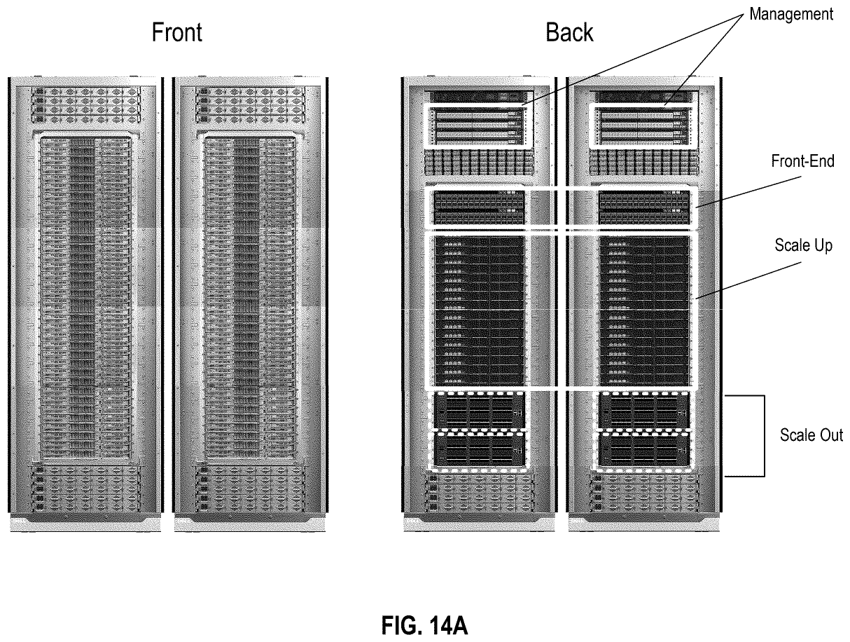

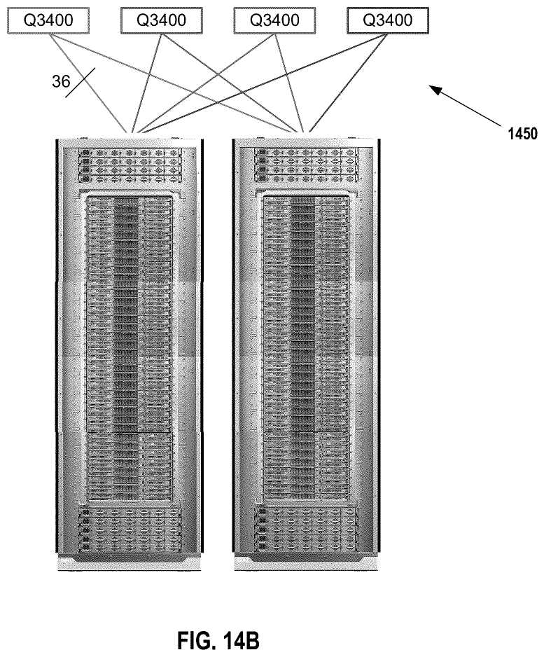

Such a design enables a compact Scalable Unit (SU), able to include 288 GPUs and the switches for all fabrics (scale-up fabric, scale-out fabric, front-end fabric, and management fabric) in just four racks, as shown in FIG. 14A and FIG. 14B. The depicted embodiment of FIG. 14A and FIG. 14B utilizes a four-rail scale-out fabric implemented with four Q3400 IB switches from Nvidia. All wiring to the first-tier switches may be based on active copper cables hidden in the rack spaces. The wiring to the second-tier switches may be optical to an optical cassette, allowing easy structured cabling connectivity. FIG. 14B depicts the four-rack system with an example scale-out fabric, according to embodiments of the present disclosure.

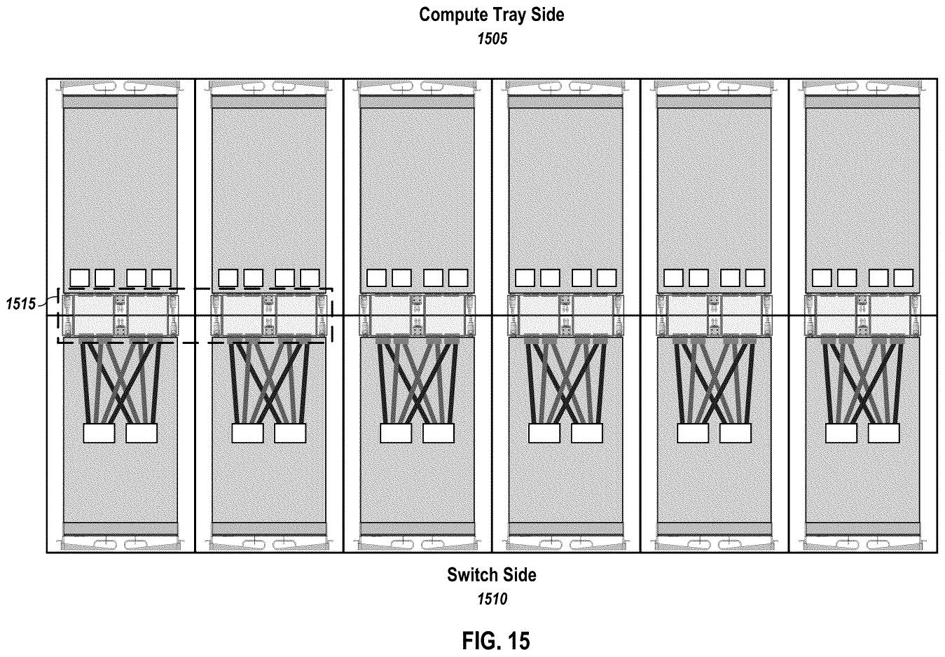

When deploying such a design, in one or more embodiments, rather than having a cold aisle and a hot aisle, a data center may have a GPU compute aisle (from where one may access and service the compute sleds) and a switches-and-utilities aisle (from where one may access and service the scale-up fabric switches and the other utilities). Such embodiments make good sense in a world that moves toward direct liquid cooling and that does not require any more air cooling. FIG. 15 depicts a data center layout with a compute tray side 1505 and a switch side 1510, according to embodiments of the present disclosure. Also illustrated in dashed lines 1515 is the positioning of the interconnect cable system 1515 for a set of racks. Note that the positioning of the interconnect cable system 1515 facilitates connection to the compute trays and the switch trays as well as the cabling and other features (e.g., supports power bar, cooling, etc.).

### 2. Heterogenous Rack Embodiments

It shall be noted that alternative configurations may also be employed. For example, embodiments may comprise a mixture of compute trays and switches in a single rack. One or more of such embodiments may provide additional benefits. For example, in the case of a homogenous rack embodiment that has an interconnect cable cartridge system that is 36 RUs high (in comparison to the 27 RUs of the cartridges in the NVL72 design), the copper cables inside the cartridges are longer, which may adversely affect the signal integrity properties. For example, as the length of copper cables increases, the signal strength diminishes due to resistance, leading to signal attenuation, and signal attenuation is more pronounced at higher data rates. Second, longer copper cables are more susceptible to electromagnetic (EM) interference from external sources or even adjacent cables, which can degrade the signal quality. At the speed of interest for the typical application of such systems (e.g., 200 Gb/s), the maximum useable length of a copper cable may be between 1 and 2 meters.

While copper-based cabling has some limitations, it also has some very significant advantages. One of the primary examples is cost. Copper cables—especially relative to fiber optic cabling—are less expensive, both in terms of initial purchase and installation. Given the staggering number of cables needed for large-scale deployments, these costs differences provide significant savings. Also, copper cables are easier to install and terminate compared to fiber optic cables. Their simplicity reduces installation time and costs. Finally, copper cables are more durable and less prone to physical damage compared to fiber optic cables. They can withstand bending and pulling without significant performance degradation.

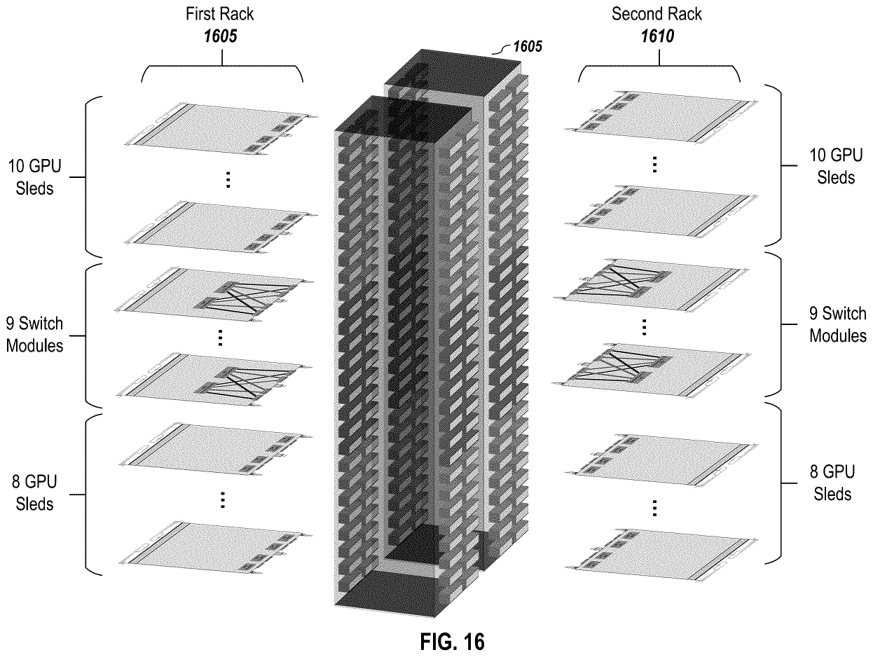

Accordingly, embodiments, like the example depicted in FIG. 16, allow for copper-based interconnect cabling systems without significant signal attenuation issues. FIG. 16 illustrates a rack implementation that supports up to double the number of compute trays than current state-of-the-art products while allowing for copper-base cabling for the scale-up fabric, according to embodiments of the present disclosure.

FIG. 16 depicts a scalable unit housing 144 GPUs system, which is able to utilize all copper-based connections in the cartridges of the interconnect cable system 1605 for the scale-up fabric, according to embodiments of the present disclosure. Note that, in contrast to the prior embodiments that contained homogeneous trays within a rack, FIG. 16 comprises a heterogeneous rack or racks, in which a single rack houses both compute trays and switch modules.

The depicted embodiment shown in FIG. 16 is based on back-to-back racks. Such embodiments have at least a couple of advantages. First, the first rack 1605 may be the same as the second rack 1610, making it easier for manufacturing, ordering, installation, etc. Second, the cartridges with the connectors of the interconnection cable system 1605 may be positioned at the same height of an NVL72 system by replicating on the second rack the same compute sled and switch layout as in the first rack. It shall be noted, however, that different configurations and different alignments may be used.

By allowing the switches to be centrally located, the maximum distance or length from the extreme compute trays at the top or bottom to the extreme switch module at the bottom or top can be kept below a maximum or threshold length. Of course, like the prior embodiments, all of this can be accomplished while dramatically increasing (e.g., doubling) the number of GPUs that can be connected by a single scale-up fabric.

### 3. Installation Embodiments

As presented above, embodiments comprise using two racks coupled through their back (or a double deepness rack). It shall be noted that, while embodiments present racks oriented with their backs facing each other, they may be oriented differently. For example, if the connectors to the compute trays and the switches were located on their sides, the racks may be positioned beside each other with the interconnect cable system between them.

In one or more embodiments, the compute sleds/trays may be installed in one rack or both racks, and the scale-up fabric switches may be installed in the other rack or both racks. The compute trays and the scale-up fabric switches may be connected through a vertical interconnect cable system (or vertical passive cartridges system). Depending upon implementation, other switches and devices may be installed in one or more of the racks (e.g., management devices, front-end switches, scale-out switches, etc.).

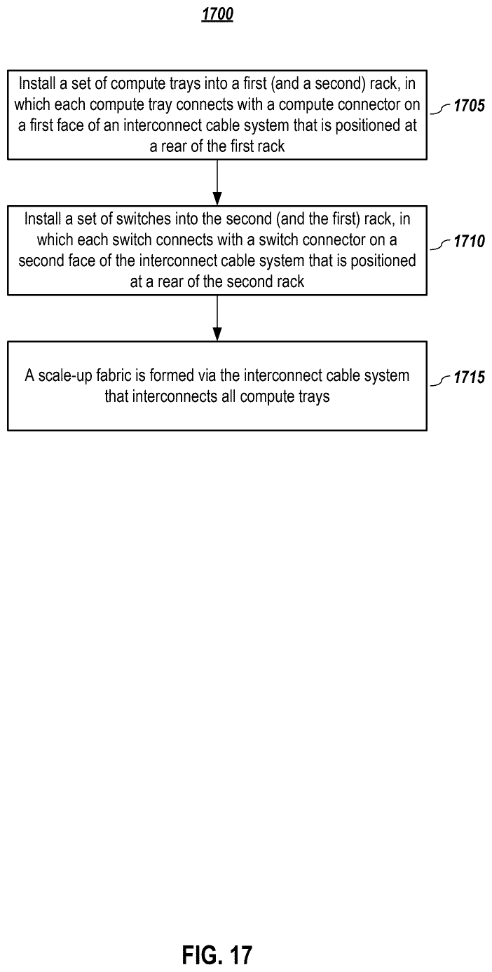

FIG. 17 depicts an example method for forming a dual-rack system, according to embodiments of the present disclosure. In one or more embodiments, a set of compute trays are installed (1705) into a first rack, in which each compute tray connects with a compute connector on a first face of an interconnect cable system that is positioned at a rear of the first rack. The interconnect cable system may comprise a first face comprising compute connectors configured to interface with compute trays housed within the first rack, a second face opposed the first face comprising switch connectors configured to interface with switches housed within a second rack, and cable connectors that connect at least some of the compute connectors to one or more switch connectors. In one or more embodiments, a set of switches are installed (1710) into the second rack, in which each switch connects with a switch connector on a second face of the interconnect cable system that is positioned at a rear of the second rack.

When the compute trays and switch modules are installed, a scale-up fabric may be formed (1715) using one or more rack systems, in which a rack system comprise modules (e.g., compute trays and switch modules) that are connected via an interconnect cable system.

It shall be noted that, in one or more embodiments, in a rack system the interconnect cable system may comprise separate interconnect cable subsystems. For example, a rack system may employ two or more interconnect cable systems/subsystems that form (functionally, physically, or both) a single interconnect cable system for the rack.

Note that depending upon the implementation, a set of compute trays may be installed into the second rack and/or a set of switches may be installed into the first rack.

Embodiments of the present disclosure possess a number of advantages. First, the resulting design allows for up to at least double the capacity of compute trays that are supported by a single scale-up fabric. Second, embodiments allow for reusing existing active components and their full serviceability. Third, depending upon configuration, embodiments allow for copper-base cabling (e.g., copper twin-axial cabling); however, it shall be noted that embodiments are not limited to just copper. Any embodiment may use a mixture of copper and optical cabling or may use optical cabling. Fourth, embodiments may be used in an NVIDIA solution context and/or may also be used with other vendors (e.g., AMD and Intel). Fifth, both the compute trays and the switch modules may be serviced from their front faces as is typically performed. One skilled in the art shall recognize additional advantages to one or more of the embodiments discussed herein.

### C. Information Handling System (IHS) and IHS-Related Embodiments

In one or more embodiments, aspects of the present patent document may be directed to, may include, or may be implemented on one or more information handling systems (or computing systems). An information handling system/computing system may include any instrumentality or aggregate of instrumentalities operable to compute, calculate, determine, classify, process, transmit, receive, retrieve, originate, route, switch, store, display, communicate, manifest, detect, record, reproduce, handle, or utilize any form of information, intelligence, or data. For example, a computing system may be or may include a personal computer (e.g., laptop), tablet computer, mobile device (e.g., personal digital assistant (PDA), smart phone, phablet, tablet, etc.), smart watch, server (e.g., blade server or rack server), a network storage device, camera, or any other suitable device and may vary in size, shape, performance, functionality, and price. The computing system may include random access memory (RAM), one or more processing resources such as a central processing unit (CPU) or hardware or software control logic, read only memory (ROM), and/or other types of memory. Additional components of the computing system may include one or more drives (e.g., hard disk drives, solid state drive, or both), one or more network ports for communicating with external devices as well as various input and output (I/O) devices. The computing system may also include one or more buses operable to transmit communications between the various hardware components.

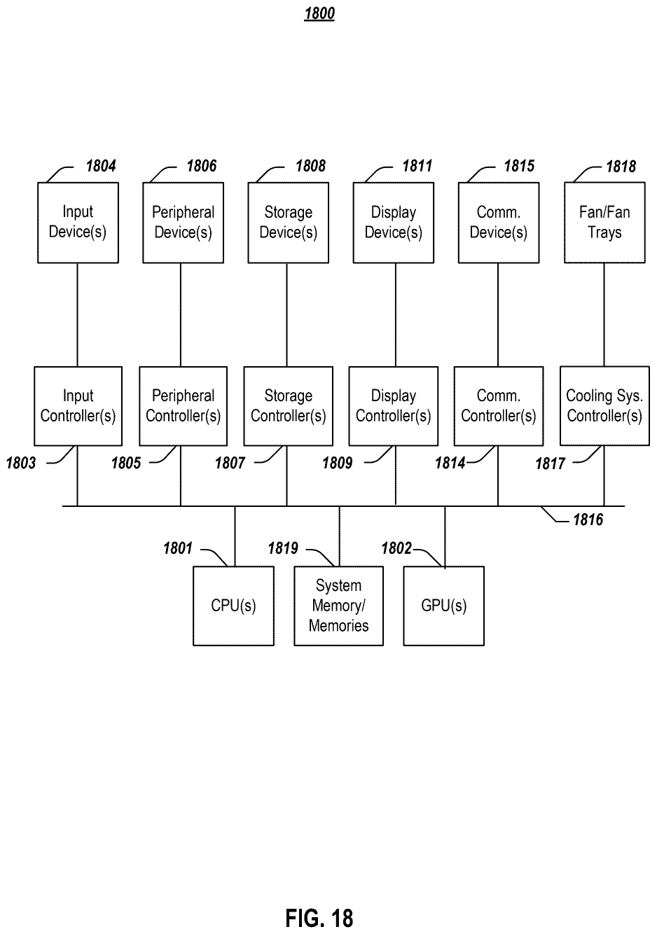

FIG. 18 depicts a simplified block diagram of an information handling system (or computing system), according to embodiments of the present disclosure. It will be understood that the functionalities shown for system 1800 may operate to support various embodiments of a computing system—although it shall be understood that a computing system may be differently configured and include different components, including having fewer or more components as depicted in FIG. 18.

As illustrated in FIG. 18, the computing system 1800 includes one or more CPUs 1801 that provides computing resources and controls the computer. CPU 1801 may be implemented with a microprocessor or the like and may also include one or more graphics processing units (GPU) 1802 and/or a floating-point coprocessor for mathematical computations. In one or more embodiments, one or more GPUs 1802 may be incorporated within the display controller 1809, such as part of a graphics card or a subcomponent. In one or more embodiments, the system may alternatively or additionally include one or more data processing units (DPUs) (not shown). In the realm of data centers and cloud computing, a DPU refers to a specialized processing unit designed to accelerate data processing tasks. DPUs are typically optimized for handling data-centric workloads such as networking, storage, security, and other tasks related to data processing and manipulation. DPUs often offload specific tasks from a main CPU, allowing for improved performance, efficiency, and scalability in data-intensive applications. They may include specialized hardware components and dedicated software to efficiently process and manage data flows within a system. The system 1800 may also include a system memory 1819, which may comprise RAM, ROM, or both.

A number of controllers and peripheral devices may also be provided, as shown in FIG. 18. An input controller 1803 represents an interface to various input device(s) 1804, such as a keyboard, mouse, touchscreen, stylus, microphone, camera, trackpad, display, etc. The computing system 1800 may also include a storage controller 1807 for interfacing with one or more storage devices 1808 each of which includes a storage medium such as magnetic tape or disk, or an optical medium that might be used to record programs of instructions for operating systems, utilities, and applications, which may include embodiments of programs that implement various aspects of the present disclosure. Storage device(s) 1808 may also be used to store processed data or data to be processed in accordance with the disclosure. The system 1800 may also include a display controller 1809 for providing an interface to a display device 1811, which may be a cathode ray tube (CRT) display, a thin film transistor (TFT) display, organic light-emitting diode, electroluminescent panel, plasma panel, or any other type of display. The computing system 1800 may also include one or more peripheral controllers or interfaces 1805 for one or more peripherals 1806. Examples of peripherals may include one or more printers, scanners, input devices, output devices, sensors, and the like. A communications controller 1814 may interface with one or more communication devices 1815, which enables the system 1800 to connect to remote devices through any of a variety of networks including the Internet, a cloud resource (e.g., an Ethernet cloud, a Fibre Channel over Ethernet (FCoE)/Data Center Bridging (DCB) cloud, etc.), a local area network (LAN), a wide area network (WAN), a storage area network (SAN) or through any suitable electromagnetic carrier signals including infrared signals. As shown in the depicted embodiment, the computing system 1800 comprises one or more fans or fan trays 1818 and a cooling subsystem controller or controllers 1817 that monitors heat/thermal temperature(s) of the system 1800 (or components thereof) and operates the fans/fan trays 1818 to help regulate the temperature.

In the illustrated system, all major system components may connect to a bus 1816, which may represent more than one physical bus. However, various system components may or may not be in physical proximity to one another. For example, input data and/or output data may be remotely transmitted from one physical location to another. In addition, programs that implement various aspects of the disclosure may be accessed from a remote location (e.g., a server) over a network. Such data and/or programs may be conveyed through any of a variety of machine-readable media including, for example: magnetic media such as hard disks, floppy disks, and magnetic tape; optical media such as compact discs (CDs) and holographic devices; magneto-optical media; and hardware devices that are specially configured to store or to store and execute program code, such as application specific integrated circuits (ASICs), programmable logic devices (PLDs), flash memory devices, other non-volatile memory (NVM) devices (such as 3D XPoint-based devices), and ROM and RAM devices.

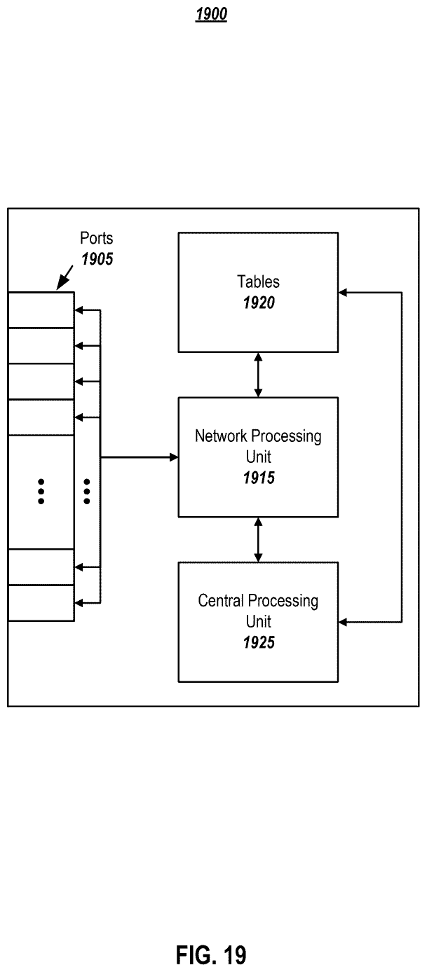

FIG. 19 depicts an alternative block diagram of an information handling system, according to embodiments of the present disclosure. It will be understood that the functionalities shown for system 1900 may operate to support various embodiments of the present disclosure—although it shall be understood that such system may be differently configured and include different components, additional components, or fewer components.

The information handling system 1900 may include a plurality of I/O ports 1905, a network processing unit (NPU) 1915, one or more tables 1920, and a CPU 1925. The system includes a power supply (not shown) and may also include other components, which are not shown for sake of simplicity.

In one or more embodiments, the I/O ports 1905 may be connected via one or more cables to one or more other network devices or clients. The network processing unit 1915 may use information included in the network data received at the node 1900, as well as information stored in the tables 1920, to identify a next device for the network data, among other possible activities. In one or more embodiments, a switching fabric may then schedule the network data for propagation through the node to an egress port for transmission to the next destination.

Aspects of the present disclosure may be encoded upon one or more non-transitory computer-readable/processor-readable/information-handling-system-readable media comprising one or more sequences of instructions, which, when executed by one or more processors or processing units, causes steps to be performed. It shall be noted that the one or more non-transitory computer-readable media shall include volatile and/or non-volatile memory. It shall be noted that alternative implementations are possible, including a hardware implementation or a software/hardware implementation. Hardware-implemented functions may be realized using ASIC(s), programmable arrays, digital signal processing circuitry, or the like. Accordingly, the “means” terms in any claims are intended to cover both software and hardware implementations. Similarly, the term “computer-readable medium or media” as used herein includes software and/or hardware having a program of instructions embodied thereon, or a combination thereof. With these implementation alternatives in mind, it is to be understood that the figures and accompanying description provide the functional information one skilled in the art would require to write program code (i.e., software) and/or to fabricate circuits (i.e., hardware) to perform the processing required.

It shall be noted that embodiments of the present disclosure may further relate to computer products with a non-transitory, tangible computer-readable medium that has computer code thereon for performing various computer-implemented operations. The media and computer code may be those specially designed and constructed for the purposes of the present disclosure, or they may be of the kind known or available to those having skill in the relevant arts. Examples of tangible computer-readable media include, for example: magnetic media such as hard disks, floppy disks, and magnetic tape; optical media such as compact discs (CDs) and holographic devices; magneto-optical media; and hardware devices that are specially configured to store or to store and execute program code, such as ASICs, PLDs, flash memory devices, other non-volatile memory devices (such as 3D XPoint-based devices), ROM, and RAM devices. Examples of computer code include machine code, such as produced by a compiler, and files containing higher level code that are executed by a computer using an interpreter. Embodiments of the present disclosure may be implemented in whole or in part as machine-executable instructions that may be in program modules that are executed by a processing device. Examples of program modules include libraries, programs, routines, objects, components, and data structures. In distributed computing environments, program modules may be physically located in settings that are local, remote, or both.

One skilled in the art shall recognize no computing system or programming language is critical to the practice of the present disclosure. One skilled in the art will also recognize that a number of the elements described above may be physically and/or functionally separated into modules and/or sub-modules or combined together.

It will be appreciated by those skilled in the art that the preceding examples and embodiments are exemplary and not limiting to the scope of the present disclosure. It is intended that all permutations, enhancements, equivalents, combinations, and improvements thereto that are apparent to those skilled in the art upon a reading of the specification and a study of the drawings are included within the true spirit and scope of the present disclosure. It shall also be noted that elements of any claim may be arranged differently including having multiple dependencies, configurations, and combinations.

What is claimed is:

1. A system comprising:
an interconnect cable system comprising:
a first face comprising:
a first set of compute connectors configured to interface with a first set of compute trays housed within a first rack; and
a first set of switch connectors configured to interface with a first set of switches housed within the first rack;
a second face comprising:
a second set of compute connectors configured to interface with a second set of compute trays housed within a second rack; and
a second set of switch connectors configured to interface with a second set of switches housed within the second rack; and
cable connectors that connect:
at least some of the compute connectors from the first set of compute connectors to one or more switch connectors from:
the first set of switch connectors;
the second set of switch connectors; or
both the first and second sets of switch connectors;
at least some of the compute connectors from the second set of compute connectors to one or more switch connectors from:
the first set of switch connectors;
the second set of switch connectors; or
both the first and second sets of switch connectors;
at least some of the compute connectors from the first and second sets of compute connectors to one or more switch connectors from:
the first set of switch connectors;
the second set of switch connectors; or
both the first and second sets of switch connectors; or
a combination thereof.

2. The system of claim 1 wherein the cable connectors connect each compute connector of the first and second sets of compute connectors to each of the switch connectors from the first and second sets of switch connectors so that each compute tray installed in its compute connector can communicate with each other compute tray via at least one of the switches from the first and second sets of switches.

3. The system of claim 1 wherein the cable connectors are copper-based cable connectors.

4. The system of claim 3 wherein each copper-based cable connector is less than a threshold distance.

5. The system of claim 1 the cable connectors comprise:
copper-based cable connectors;
optics-based cable connectors; or
a combination of both.

6. The system of claim 1 wherein the interconnect cable system further comprises space to accommodate at least part of a cooling system to manage generated heat.

7. The system of claim 1 further comprising the first rack and the second rack in which the interconnect cable system is positioned between a backside of the first rack and a backside of the second rack.

8. A system comprising:
an interconnect cable system comprising:
a first face comprising:
compute connectors configured to interface with compute trays housed within a first rack;
a second face opposed the first face comprising:
switch connectors configured to interface with switches housed within the second rack; and
cable connectors that connect at least some of the compute connectors to one or more switch connectors.

9. The system of claim 8 wherein the cable connectors connect each compute connector to each of the switch connectors so that each compute tray installed in its compute connector can communicate with each other compute tray via at least one of the switches.

10. The system of claim 8 wherein the cable connectors are copper-based cable connectors.

11. The system of claim 10 wherein each copper-based cable connector is less than a threshold distance.

12. The system of claim 8 the cable connectors comprise:
copper-based cable connectors;
optics-based cable connectors; or
a combination of both.

13. The system of claim 8 wherein the interconnect cable system further comprises space to accommodate at least part of a cooling system to manage generated heat.

14. The system of claim 8 further comprising the first rack and the second rack in which the interconnect cable system is positioned between a backside of the first rack and a backside of the second rack.

15. A method for forming a dual-rack system comprising:
installing a set of compute trays into a first rack, in which each compute tray connects with a compute connector on a first face of an interconnect cable system that is positioned at a rear of the first rack, the interconnect cable system comprising:
the first face comprising compute connectors configured to interface with compute trays housed within the first rack;
a second face opposed the first face comprising switch connectors configured to interface with switches housed within a second rack; and
cable connectors that connect at least some of the compute connectors to one or more switch connectors; and
installing a set of switches into the second rack, in which each switch connects with a switch connector on a second face of the interconnect cable system that is positioned at a rear of the second rack.

16. The method of claim 15 wherein:
the first face of the interconnect cable system comprises compute connectors and no switch connectors; and
the second face of the interconnect cable system comprises switch connectors and no compute connectors.

17. The method of claim 15 wherein:
the first face of the interconnect cable system comprises compute connectors and switch connectors; and
the second face of the interconnect cable system comprises switch connectors and compute connectors.

18. The method of claim 15 wherein the first face of the interconnect cable system comprises one or more switch connectors and the second face of the interconnect cable system comprises one or more compute connectors and the method further comprises:
installing a second set of compute trays into the second rack, in which each compute tray connects with a compute connector on the second face of the interconnect cable system; and
installing a second set of switches into the first rack, in which each switch connects with a switch connector on the first face of the interconnect cable system.

19. The method of claim 15 wherein the cable connectors are copper-based cable connectors.

20. The method of claim 15 wherein each copper-based cable connector is less than a threshold distance.
